(19) United States
(12) Patent Application Publication
(10) Pub. No.: US 2012/0261744 A1
(43) Pub. Date: Oct. 18, 2012

(54) MICROELECTRONIC DEVICE STRUCTURE AND MANUFACTURING METHOD THEREOF

(75) Inventors: Pengfei Wang, Shanghai (CN); Qingqing Sun, Shanghai (CN); Shijin Ding, Shanghai (CN); Wei Zhang, Shanghai (CN)

(73) Assignee: Fudan University, Shanghai (CN)

(21) Appl. No.: 13/378,114

(22) PCT Filed: Dec. 24, 2010
(86) PCT No.: PCT/CN2010/002151

§ 371 Date: Dec. 14, 2011

(30) Foreign Application Priority Data
Dec. 24, 2009 (CN) 200910200624.7
Dec. 24, 2009 (CN) 200910200625.1

(51) Int. Cl. H01L 29/78; H01L 21/336

(52) U.S. Cl. 257/329; 438/270; 257/E29.262; 257/E21.41

(57) ABSTRACT

The present invention refers to a semiconductor device especially a tunneling filed effect transistor (TFET) using narrow bandgap material as the source electrode material. A Semiconductor device which is a tunneling field effect transistor type semiconductor device, in which the source material is characterized as narrow band-gap material; meanwhile, there is a u-groove channel. The narrow band-gap material results in a raise of driving current and the u-groove channel reduced drain leakage current. The TFET disclosed in to present invention has the advantages of low leakage current, high drive current, and high integration density. The static power consumption is also reduced by using the present invention. The integration density is improved as well.

### FIELD OF INVENTION

This invention relates to a kind of transistor, especially a tunneling filed effect transistor (TFET) using narrow bandgap material as the source electrode material.

### BACKGROUND OF THE INVENTION

Recently, the Si-based semiconductor technology has been improved a lot. The development follows the Moore's law that the density of integrated circuit doubles every 18 months. With the development of integrated circuit technology, the size of Metal-oxide-silicon field effect transistor (MOSFET) is getting smaller and the transistor density on unit array is getting higher. The short-channel effects of MOSFET are becoming even more serious. Short channel effects will deteriorate the chip performance; even the chip functionality can be destroyed.

Nowadays, the semiconductor device is at around 50 nm technology node, the leakage current between the source and drain electrodes increases rapidly with the decreasing channel length. It is necessary to use a new device for low leakage current and reduce power dissipation beyond 30 nm technology. Tunneling-field effect transistor has a very low leakage current. It can reduce the chip size and lower the supply voltage. Although the leakage current of tunneling-field effect transistor is lower than the traditional MOSFET, the leakage current of tunneling-field effect transistor is also increasing when the channel is shortening. Therefore, with the gate length of 20 nm, the drain leakage current of conventional planar-channel tunneling-field effect transistor will also increase. The drive current of TFET is 3 to 4 orders of magnitude lower than that of MOSFET. Thus the drive current of TFET needs to be improved for better chip performance. In the current available technologies, a TFET with improved drive current will also have a increased leakage current deteriorating the chip performance.

### BRIEF SUMMARY OF THE INVENTION

In view of that, the present invention intends to propose a TFET semiconductor device with increased drive current and lowered leakage current. At the same time, the method of manufacturing will also be proposed.

The present invention discloses a TFET semiconductor device with source electrode made of narrow band-gap material. Because of application of narrow band-gap material, an increased drive current can be achieved. At the same time, the leakage current of the proposed TFET is suppressed due to the increased channel length by using U-shaped channel. Therefore, the leakage current of the TFET is suppressed while the drive current is improved.

A Semiconductor device which is a tunneling field effect transistor type semiconductor device, in which the source material is characterized as narrow band-gap material; meanwhile, there is a u-groove channel.

the said narrow band-gap material is SiGe.

the said tunneling field effect transistor is the complementary tunneling field effect transistor, composed by the n-type and p-type TFET which have source regions made of narrow band-gap materials.

the said narrow band-gap material of the said n-type TFET is SiGe or Ge.

the said narrow band-gap material of the said p-type TFET is made of InGaAs or AlGaAs.

A method of making the semiconductor device, containing the following processes:

providing a semiconductor substrate,

forming the drain doping region with a first conductivity type,

etching a U-groove channel recessed into the said semiconductor substrate,

depositing oxide dielectric layer and high-k layer in sequence,

forming the gate structure,

etching out part of the said high-k material, oxide dielectric layer and substrate,

growing narrow band-gap material in the said source region,

implanting dopant ions of the second conductivity type,

forming contacts and interconnection.

A method of manufacturing semiconductor device, comprising the following process steps:

providing a semiconductor substrate,

forming a region with the first conductivity type,

forming a region with the second conductivity type,

forming a U-shaped channel structure by lithography and etching;

depositing a gate stack material containing silicon dioxide layer, a high-k dielectric layer, a first conductive layer, and a hard mask layer,

etching the said silicon dioxide layer, high-k dielectric layer, conductive layer, and hard mask layer, and forming a gate structure,

depositing a first insulator layer and forming a gate spacer structure by etching back,

selectively etching out a first part of the substrate,

epitaxying selectively, forming a first doped region with narrow band-gap material,

selectively etching out a second part of the substrate,

epitaxying selectively, forming a second doped region with narrow band-gap material,

forming contacts and metallization structure.

### BRIEF DESCRIPTION OF THE SEVERAL VIEWS OF THE DRAWINGS

FIG. 1 illustrates the substrate according for fabricating according to the claims.

FIG. 2 illustrates the photo resist deposition, lithography, and n⁺ ion implantation, according to one of the embodiments.

FIG. 3 illustrates the U-shape structure formation by using lithography and the following etch step, according to one of the embodiments.

FIG. 4 illustrates the structure after deposition of oxide dielectric, high-k material, metal, poly-Si, and photoresist according to one of the embodiments.

FIG. 5 illustrates the structure after the etching of oxide dielectric, high-k material, metal, and poly-Si, according to one of the embodiments.

FIG. 6 illustrates the structure after the etching of oxide dielectric, high-k material, metal, and poly-Si, according to one of the embodiments.

FIG. 7 illustrates the structure after the etching of photoresist, interlayer dielectric, and substrate, according to one of the embodiments.

FIG. 8 illustrates the structure after p⁺ ion implantation, according to one of the embodiments.

FIG. 9 illustrates the cross-sectional views along the channel direction of a fabricated recessed-channel (or U-shape) tunneling-field effect transistor, according to one of the embodiments.

FIG. 10 illustrates the substrate according to one of the embodiments.

FIG. 11 illustrates the structure after the first conductive type ion implantation, according to one of the embodiments.

FIG. 12 illustrates the structure after the second conductive type ion implantation, according to one of the embodiments.

FIG. 13 illustrates the structure after the formation of U-shape channel, according to one of the embodiments.

FIG. 14 illustrates the structure after deposition of gate oxide dielectric, high-k material, metal, poly-Si, and photoresist according to one of the embodiments.

FIG. 15 illustrates the structure after forming the gate patterning, according to one of the embodiments.

FIG. 16 illustrates the structure after forming a silicon oxide layer by oxidation, according to one of the embodiments.

FIG. 17 illustrates the structure after forming gate spacer, according to one of the embodiments.

FIG. 18 illustrates the structure after etching into the substrate to etch out the source part of NTFET, according to one of the embodiments.

FIG. 19 illustrates the structure after selective expitaxy of narrow band-gap material as the source part of NTFET, according to one of the embodiments.

FIG. 20 illustrates the structure after etching into the substrate to etch out the source part of PTFET, according to one of the embodiments.

FIG. 21 illustrates the structure after selective expitaxy of narrow band-gap material as the source part of PTFET, according to one of the embodiments.

FIG. 22 illustrates the cross-sectional views of the structure shown in FIG. 21 after metallization, according to one of the embodiments

### DETAILED DESCRIPTION OF THE INVENTION

In the following this invention and its embodiments will be described together with figures. In the drawings, for better illustration, the thickness between the layers and the regions is magnified, but the sizes shown do not represent the actual sizes. Although these drawings have not reflect the actual sizes of the devices accurately, they completely reflect the mutual position of the regions and the composition structures, especially the upper-lower and adjacent relations between the composition structures.

The figures are ideal schetches of the present invention. The embodiments of this invention is not limited to the specific structures shown in the figures in this invention. The structures with deviations caused by manufacturing are also included. For example, after the etching process, the structure can have rounded corners. However, in the figures of the present invention, rectangular structures are still used. That means, the figures in this invention are schetches for better understanding, but the invention scope is not limited to them. Meanwhile, the “chip” or “substrate” used in this invention can be considered as the substrate during the processes of manufacturing, and it may include other thin films fabricated on it.

### The First Embodiment

A Semiconductor device which is a tunneling field effect transistor type semiconductor device, in which the source material is characterized as narrow band-gap material; meanwhile, there is a u-groove channel. As can be seen in FIG. 9, the channel of the TFET device is U-shaped. This kind of structure can avoid the short channel effects of the conventional devices. The leakage of the device can also be reduced. At the same time, in order to improve the tunneling efficiency, narrow band-gap material is used at the source electrode region. For example, SiGe material for N-type TFET and InAsGa material for P-type TFET.

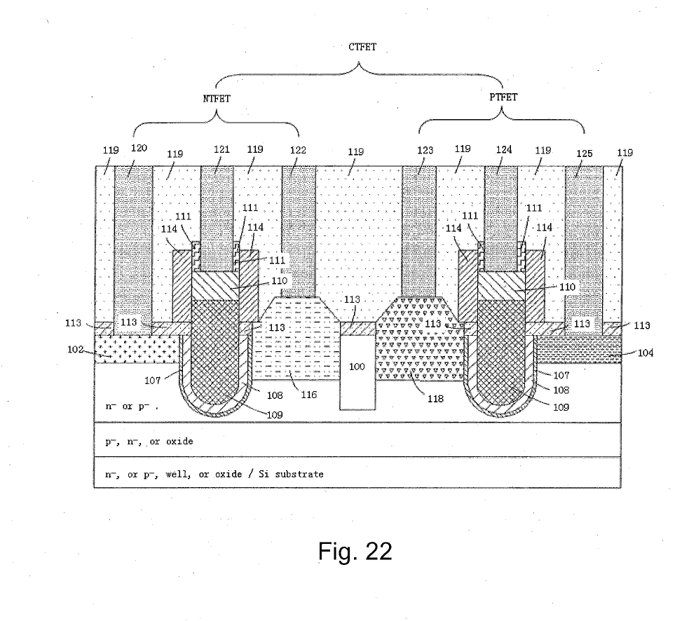

In FIG. 22, the U shape channel N-type TFET and P-type TFET according to the current invention are integrated to form an inverter made of complementary TFETs. This kind of complementary TFET circuit can enable CMOS-like functionality. Because of the low leakage current of the TFET proposed in the present invention, the standby power dissipation of the chips containing the presently invented TFET devices can be very low. At the same time, because narrow band-gap materials are used at the source region of the TFETs, the drive current can be improved and the operation speed of the complementary TFET can be improved.

### The Second Embodiment

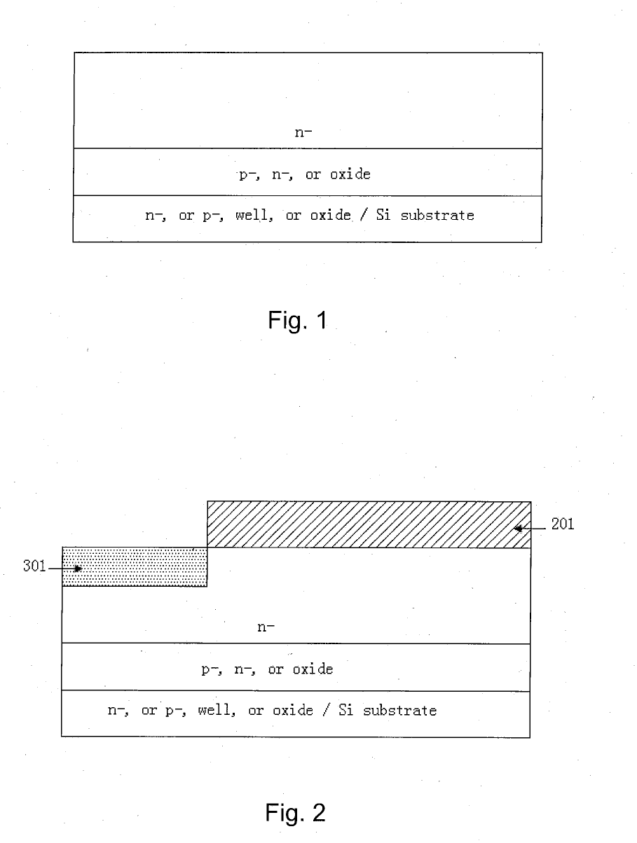

Step 1, as shown in FIG. 1, a semiconductor substrate is provided.

Step 2, as shown in FIG. 2, a thin film 201, for example, photo resist, is deposited on the said semiconductor substrate. Then, etch away part of film 201 and do ion implantation. A n⁺ region 301 is formed on the substrate by ion implantation process.

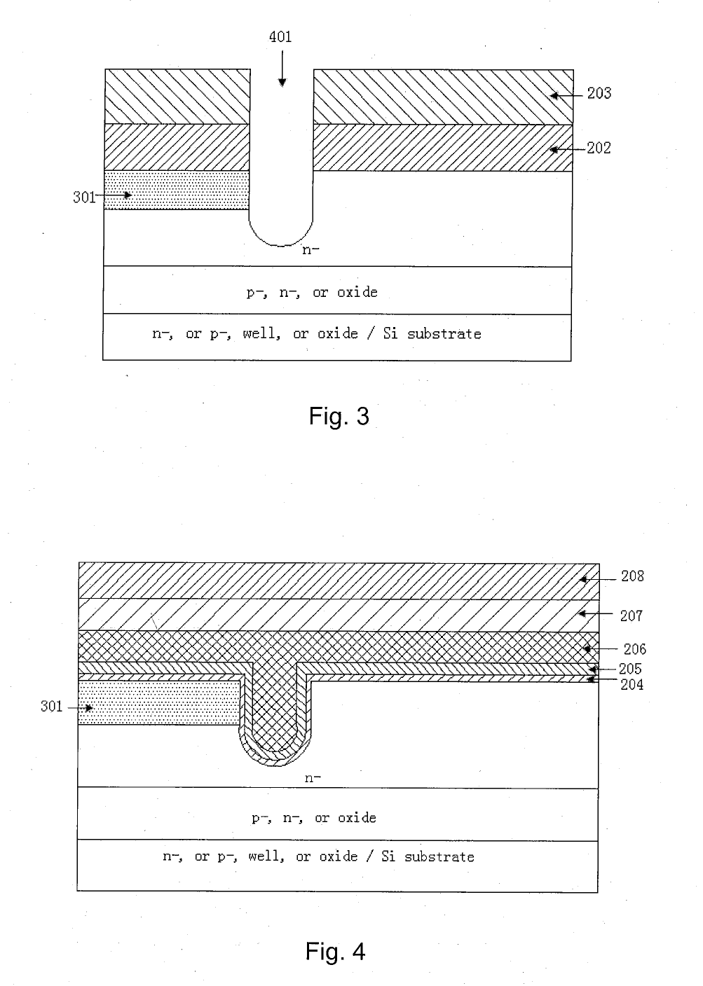

Step 3, as shown in FIG. 3, thin film 201 is removed, then a silicon dioxide layer 202 and a photoresist layer 203 are deposited. Lithography process and dry etching processes are executed to form a window 401 and recess through the silicon dioxide layer 202 and into the semiconductor substrate.

Step 4, as shown in FIG. 4, the thin films 202 and 203 are stripped away. An ultra thin silicon dioxide layer 204, a high-k dielectric layer 205 such as hafnium dioxide, a metal layer 206 such as Al, TiN or TaN, and then a poly-silicon layer 207 are deposited. Next, a photoresist layer 208 is deposited.

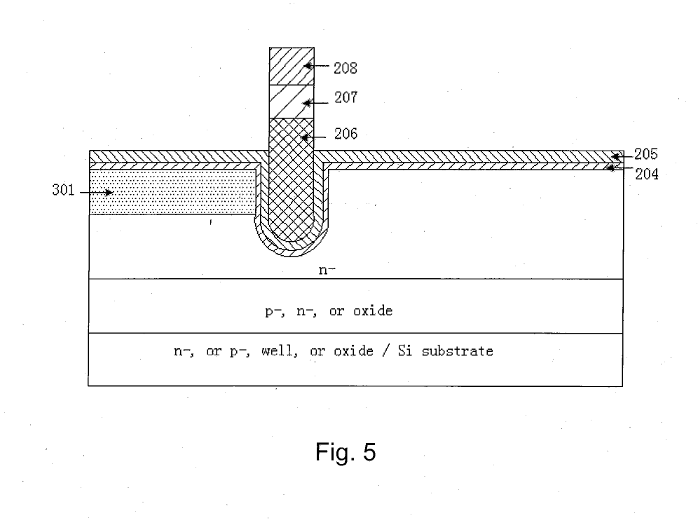

Step 5, etch films 208, 207, 206 following the lithography structure. The resulted structure is shown in FIG. 5.

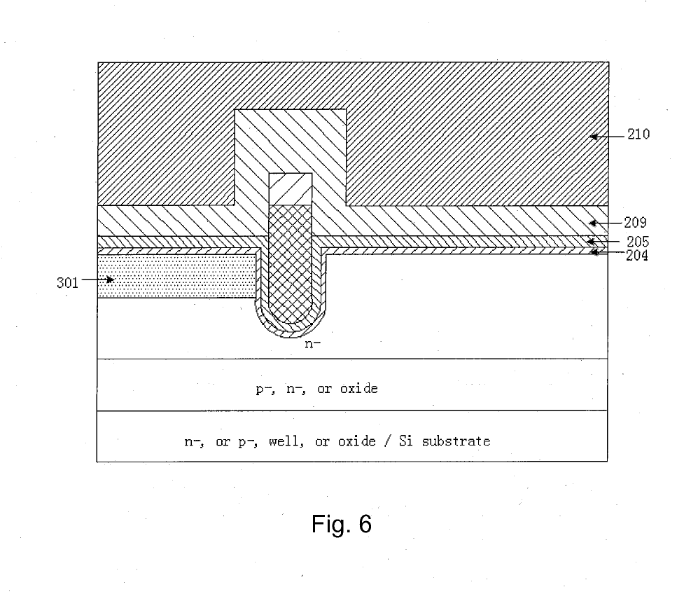

Step 6, as shown in FIG. 6, a thin film Si3N4 layer 209 is deposited. Then a photoresist layer 210 is deposited.

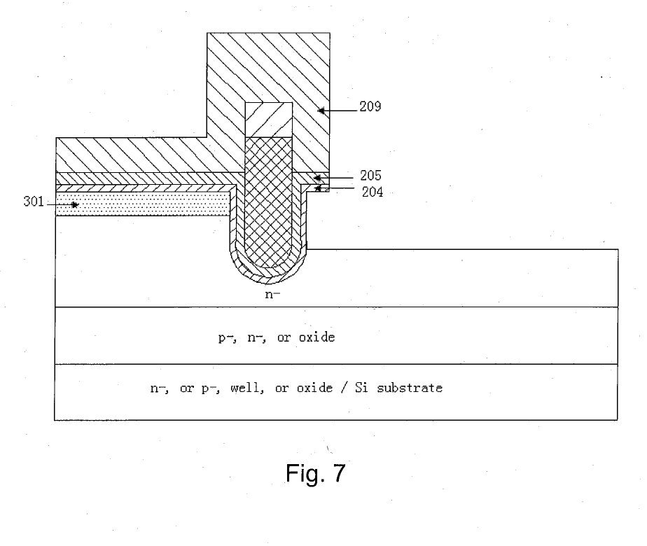

Step 7, as shown in FIG. 7, after lithography and dry etching processes, the silicon dioxide layer 209 is patterned and part of the oxide-uncovered substrate is etched away. Then remove thin film 210.

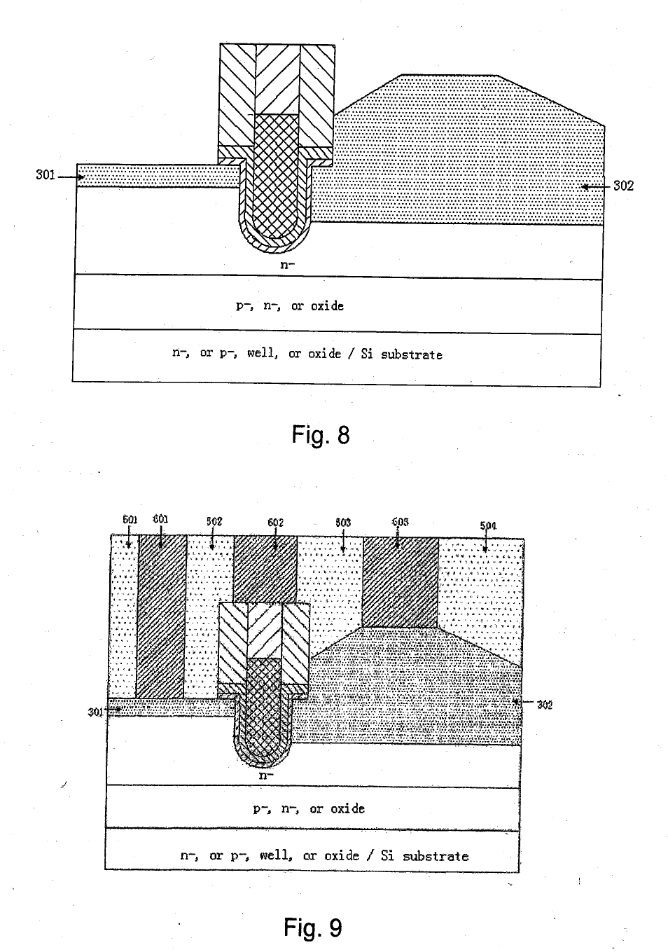

Step 8, as shown in FIG. 8, a selective expitaxy process is used to form the source region 302 with a second doping type. The source region is made of p⁺doped narrow band-gap material in order to increase the tunneling rate. Then, an anisotropic dielectric etching process is performed to form the spacer, as is widely used in the art. The resulted structure is shown in FIG. 8.

Step 9, as shown in FIG. 9, this device is metalized and passivated. Films 501, 502, 503, and 504 can be TiN, Ti, Ta or TaN. Metal lines 601, 602 and 603 are copper or tungsten.

### The Third Embodiment

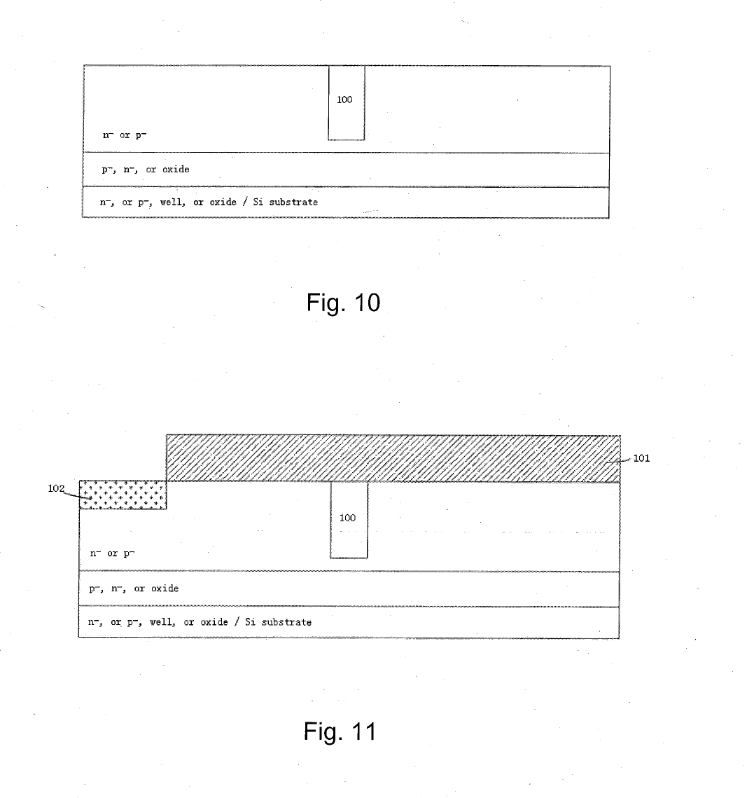

First, as shown in FIG. 10, a semiconductor substrate is provided. Structure 100 is shallow trench isolation.

Then, as shown in FIG. 11, on the said substrate a thin film (i.e. photo resist) 101 is deposited. Then part of the layer 101 is etched away. The following n⁺ ion implantation process will form a n⁺ doping region 102.

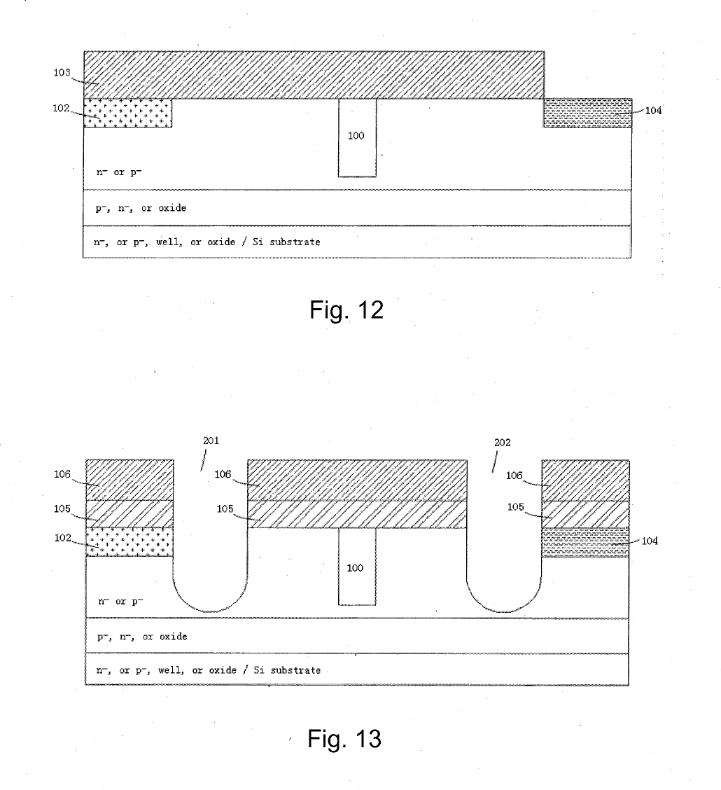

Next, as shown in FIG. 12, strip away layer 101 and deposit another photo resist layer 103. Etch part of layer 103 and do p⁺ ion implantation. A p⁺ doping region 104 is formed by ion implantation.

In FIG. 13, the layer 104 is removed, then deposit layer 105 and 106. Using lithography process and dry etching processes, the recessed region region 201 and 202 can be formed. Layers 105 and 106 are Si3N4 and photo resist, respectively.

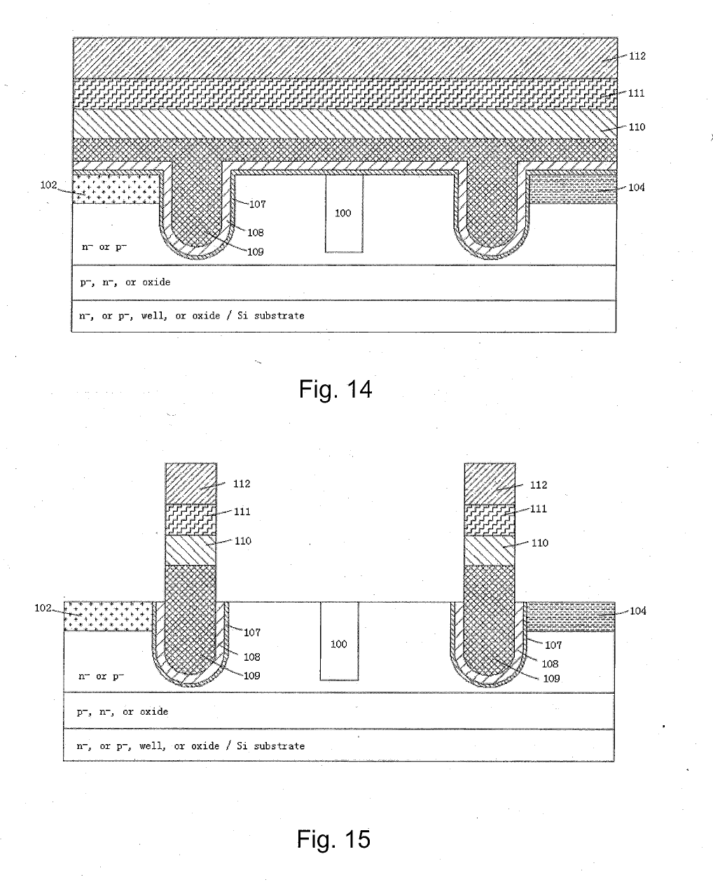

Then, as shown in FIG. 14, layers 105 and 106 are removed. Afterward, deposit thin film SiO2 layer 107, high-k layer 108, TiN or TaN layer 109, poly-Si layer 110, Si₃N₄ layer 111, and photo-resist layer 112.

Next, as shown in FIG. 15, etch the layers of 107, 108, 109, 110, 111, and 112, forming the gate electrode structure.

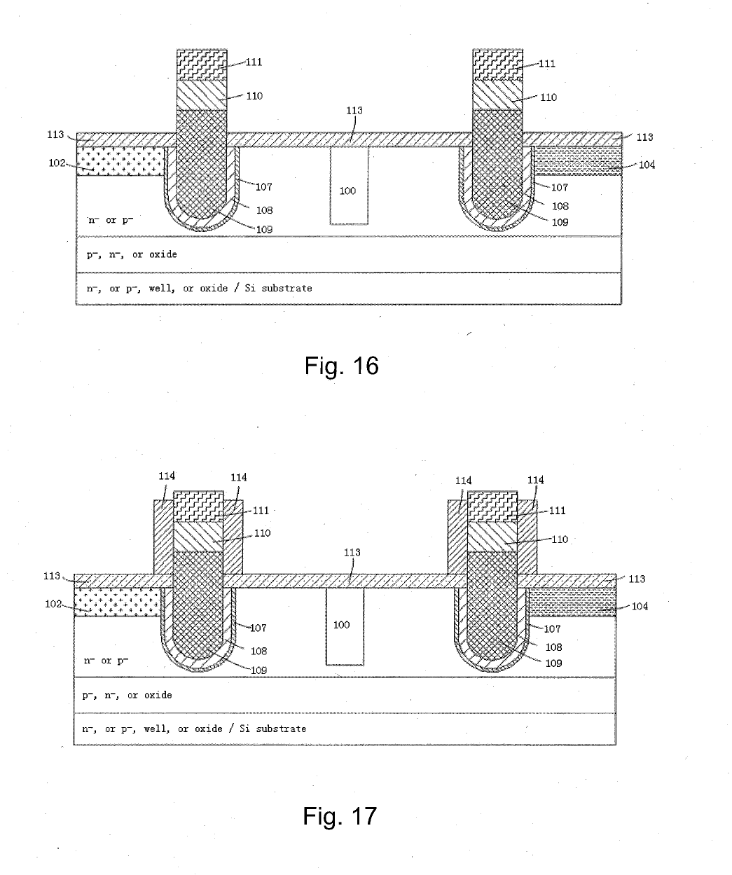

Then, as shown in FIG. 16, remove layer 112 and then deposit SiO₂ layer 113 and a photo resist layer. Afterward, etch back the layers 112 and 113. Then remove the said photoresist layer.

Next, as shown in FIG. 17, the gate spacer 114 is formed by using an anisotropic etching process. Layer 114 can be Si₃N₄.

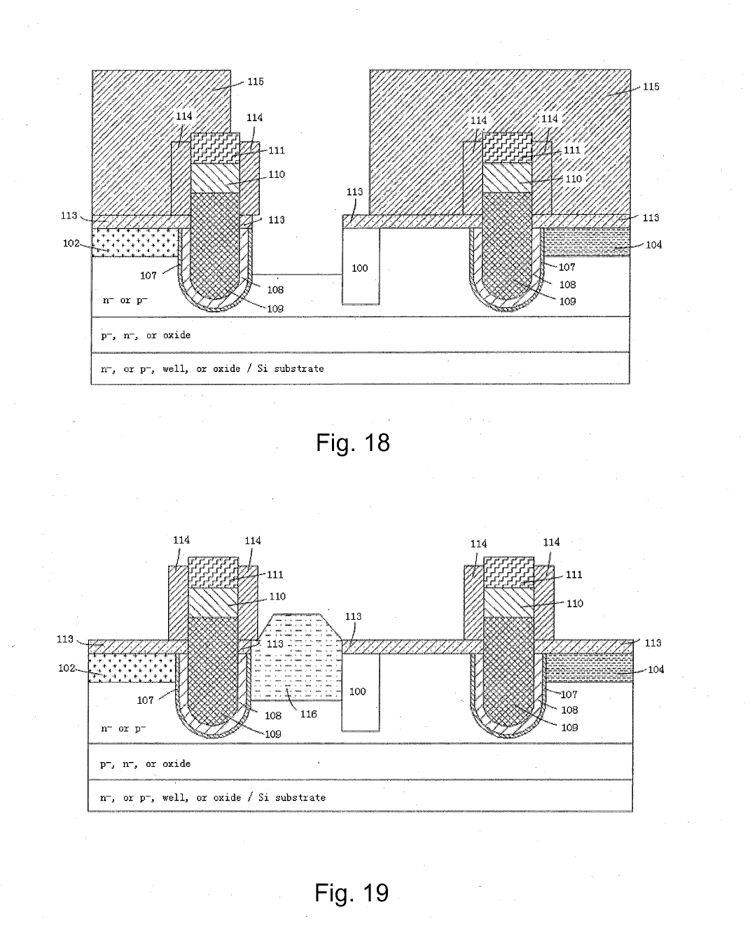

Next, as shown in FIG. 18, deposit a photo resist layer 115, then etch the said photo resist and further into the substrate.

After that, as shown in FIG. 19, remove layer 115, then a first selective epitaxy process is performed to grow narrow, band-gap material, i.e., SiGe or Ge. Region 116 is the doped epitaxial region after the first selective epitaxy processes.

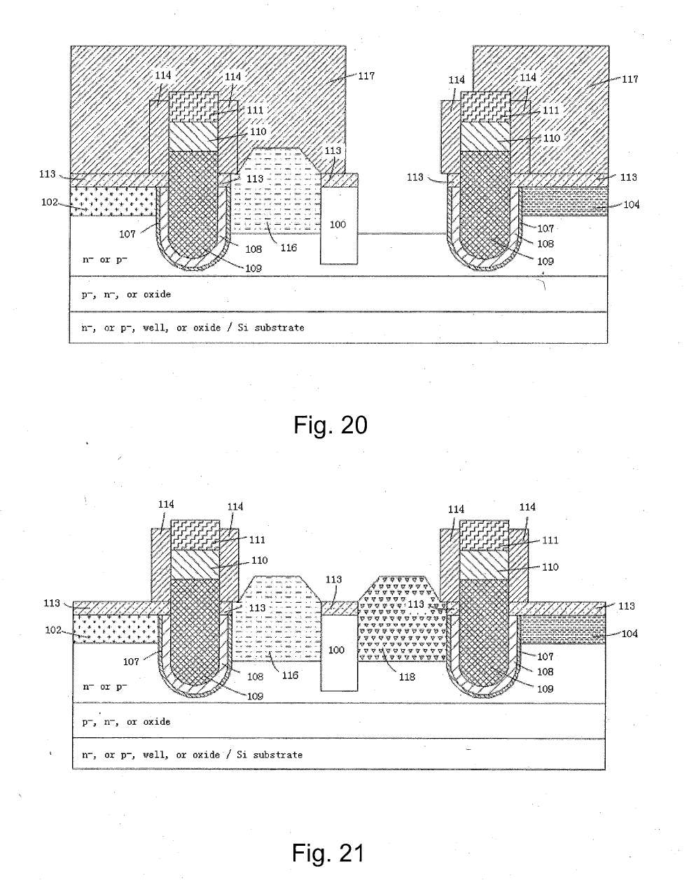

Next, as shown in FIG. 20, deposit a photo resist layer 117, then etch the said photo resist and further into the substrate.

After that, as shown in FIG. 21, remove layer 117, then a second selective epitaxy process is performed to grow narrow band-gap material, i.e., AsGa or InAsGa. Region 118 is the doped epitaxial region after the second selective epitaxy processes.

Finally, as shown in FIG. 22, the devices are interconnected. Layer 119 is TiN, Ti, Ta, or TaN. Metal line 120, 121, 122, 123, 124, and 125 are copper or tungsten.

The embodiments disclosed in the present invention enable TFET with increased drive current and decreased leakage current. They can be applied in the low power integrated circuit manufacturing.

The complementary tunneling field effect transistor disclosed in the present invention has the advantages of low leakage current, high drive current, lower power consumption, and high integration density. It can replace the CMOS technology. It is especially suitable for low power chip manufacturing.

As aforementioned, following the claims of this invention, many embodiments with modifications can be obtained. Therefore, the present invention does not limited to the embodiments disclose in the present invention except they are not included in the claims of this invention.

What is claimed is:

1. A Semiconductor device which is a tunneling field effect transistor type semiconductor device, in which the source material is characterized as narrow band-gap material; meanwhile, there is a u-groove channel.

2. The semiconductor device of claim 1, the said narrow band-gap material is SiGe.

3. The semiconductor device of claim 1, the said tunneling field effect transistor is the complementary tunneling field effect transistor, composed by the n-type and p-type TFET which have source regions made of narrow band-gap materials.

4. The semiconductor device of claim 3, the said narrow band-gap material of the said n-type TFET is SiGe or Ge.

5. The semiconductor device of claim 3, the said narrow band-gap material of the said p-type TFET is made of InGaAs or AlGaAs.

6. A method of making the semiconductor device of claim 1, containing the following processes:
providing a semiconductor substrate,
forming the drain doping region with a first conductivity type,
etching a U-groove channel recessed into the said semiconductor substrate,
depositing oxide dielectric layer and high-k layer in sequence,
forming the gate structure,
etching out part of the said high-k material, oxide dielectric layer and substrate,
growing narrow band-gap material in the said source region,
implanting dopant ions of the second conductivity type,
forming contacts and interconnection.

7. According to the method of claim 6, the first conductivity type is n-type.

8. According to the method of claim 6, the second conductivity type is p-type.

9. A method of manufacturing semiconductor device, comprising the following process steps:
providing a semiconductor substrate,
forming a region with the first conductivity type,
forming a region with the second conductivity type,
forming a U-shaped channel structure by lithography and etching;
depositing a gate stack material containing silicon dioxide layer, a high-k dielectric layer, a first conductive layer, and a hard mask layer,
etching the said silicon dioxide layer, high-k dielectric layer, conductive layer, and hard mask layer, and forming a gate structure,
depositing a first insulator layer and forming a gate spacer structure by etching back,
selectively etching out a first part of the substrate,
epitaxying selectively, forming a first doped region with narrow band-gap material,
selectively etching out a second part of the substrate,
epitaxying selectively, forming a second doped region with narrow band-gap material,
forming contacts and metallization structure.

10. The method of claim 9, wherein said substrate is bulk-silicon or silicon-on-insulator (SOI).

11. The method of claim 9, wherein said first conductivity type is doped with n-type dopant and said second conductivity type is doped with p-type dopant.

12. The method of claim 9, wherein said first conductivity type is doped with p-type dopant i and said second conductivity type is doped with n-type dopant.

13. The method of claim 9, wherein said the first conductive layer is poly-silicon, amorphous silicon, tungsten, titanium nitride or tantalum nitride.

14. The method of claim 9, wherein said hard mask is metal layer, dielectric layer, semiconductor layer or one of their combinations, it protects the conductive layer in the gate electrode during the following etching processes.

15. The method of claim 9, wherein said first insulating layer is silicon dioxide or silicon nitride or their combinations.

16. The method of claim 9, wherein said first narrow band-gap material is SiGe or Ge, said second narrow band-gap material is InGaAs or AlGaAs.

17. The method of claim 9, wherein said first narrow band-gap material is InGaAs or AlGaAs, said second narrow band-gap material is SiGe or Ge.
